(19) United States
(12) Patent Application Publication
(10) Pub. No.: US 2005/0256011 A1
(43) Pub. Date: Nov. 17, 2005

(54) System and method for quality testing of superconducting tape

(75) Inventors: Alex Ignatiev, Houston, TX (US); Alexander A. Molodyk, Houston, TX (US); Louis D. Castellani, Houston, TX (US)

Correspondence Address: DALLAS OFFICE OF FULBRIGHT & JAWORSKI L.L.P., 2200 ROSS AVENUE, SUITE 2800, DALLAS, TX, 75201-2784, US

(73) Assignee: Metal Oxide Technologies, Inc., Houston, TX (US)

(21) Appl. No.: 11/038,769

(22) Filed: Jan. 19, 2005

Related U.S. Application Data
(60) Provisional application No. 60/538,849, filed on Jan. 23, 2004.

(51) Int. Cl. H01L 39/24

(52) U.S. Cl. 505/473

(57) ABSTRACT

The present invention is directed to a system and method which imparts quality control testing to a reel-to-reel superconductor manufacturing line. The quality control testing will ensure the characteristics of the final superconductor tape, as well as the tape under process. The quality control testing may be used to control and/or change production parameters (e.g. temperature, pressure, gas concentrations, precursor amounts, etc).

### CROSS-REFERENCE TO RELATED APPLICATIONS

This application claims priority to U.S. Provisional Patent Application No. 60/538,849, the disclosure of which is hereby incorporated herein by reference. This application is related to co-pending and commonly assigned U.S. patent applications Ser. No. 10/206,123, entitled “METHOD AND APPARATUS FOR FORMING SUPERCONDUCTOR MATERIAL ON A TAPE SUBSTRATE,” filed Jul. 26, 2002, to co-pending and commonly-assigned U.S. patent application Ser. No. 10/206,900, entitled “SUPERCONDUCTOR MATERIAL ON A TAPE SUBSTRATE,” filed Jul. 26, 2002, and concurrently filed and commonly assigned U.S. patent application Ser. No. 10/206,783, entitled “METHOD AND APPARATUS FOR FORMING A THIN FILM ON A TAPE SUBSTRATE,” filed Jul. 26, 2002, to U.S. patent application Ser. No. ______ [attorney docket no. 5837-P001CP1-10311280] filed concurrently herewith and entitled “METHOD AND APPARATUS FOR FORMING SUPERCONDUCTOR MATERIAL ON A TAPE SUBSTRATE,” to U.S. patent application Ser. No. ________ [attorney docket no. 5837-P004US-10311281] filed concurrently herewith and entitled “SYSTEM AND METHOD FOR PROVIDING PRECURSORS,” and to U.S. patent application Ser. No. ______ [attorney docket no. 5837-P005US-10311282] filed concurrently herewith and entitled “SYSTEM AND METHOD FOR JOINING SUPERCONDUCTIVITY TAPE,” the disclosures of which are hereby incorporated herein by reference.

### TECHNICAL FIELD

This invention relates in general to superconductors, and in specific to methods and systems for quality testing of superconductor material.

### BACKGROUND OF THE INVENTION

Electrical resistance in metals arises because electrons that are propagating through the solid are scattered because of deviations from perfect translational symmetry. These deviations are produced either by impurities or the phonon lattice vibrations. The impurities form the temperature independent contribution to the resistance, and the vibrations form the temperature dependent contribution.

Electrical resistance, in some applications, is very undesirable. For example, in electrical power transmission, electrical resistance causes power dissipation, i.e. loss. The power dissipation grows in proportion to the square of the current, namely P=I²R in normal wires. Thus, wires carrying large currents dissipate large amounts of energy. Moreover, the longer the wire used in either larger transformers, bigger motors or larger transmission distances, the more dissipation, since the resistance in a wire is proportional to its length. Thus, as wire lengths increase more energy is lost in the wires, even with relatively small currents. Consequently, electric power plants produce more energy than that which is used by consumers, since a portion of the energy is lost due to wire resistance.

In a superconductor that is cooled below its transition temperature T_{c}, there is no resistance because the scattering mechanisms are unable to impede the motion of the current carriers. The current is carried, in most known classes of superconductor materials, by pairs of electrons known as Cooper pairs. The mechanism by which two negatively charged electrons are bound together is described by the BCS (Bardeen Cooper Schrieffer) theory. In the superconducting state, i.e. below T_{c}, the binding energy of a pair of electrons causes the opening of a gap in the energy spectrum at E_{f}, which is the Fermi energy or the highest occupied level in a solid. This separates the pair states from the “normal” single electron states. The size of a Cooper pair is given by the coherence length which is typically 1000 Å, although it can be as small as 30 Å in the copper oxides. The space occupied by one pair contains many other pairs, which forms a complex interdependence of the occupancy of the pair states. Thus, there is insufficient thermal energy to scatter the pairs, as reversing the direction of travel of one electron in the pair requires the destruction of the pair and many other pairs due to the complex interdependence. Consequently, the pairs carry current unimpeded. For further information on superconductor theory please see “Introduction to Superconductivity,” by M. Tinkham, McGraw-Hill, New York, 1975.

Many different materials can become superconductors when their temperature is cooled below T_{c}. For example, some classical type I superconductors (along with their respective T_{c}'s in degrees Kelvin (K)) are carbon 15K, lead 7.2K, lanthanum 4.9K, tantalum 4.47K, and mercury 4.47K. Some type II superconductors, which are part of the new class of high temperature superconductors (along with their respective T_{c}'s in degrees K), are Hg_{0.8}Tl_{0.2}Ba₂Ca₂Cu₃O_{8.33} 138K, Bi₂Sr₂Ca₂Cu₃O₁₀ 118 k, and YBa₂Cu₃O₇₋ₓ 93K. The last superconductor is also well known as YBCO superconductor, for its components, namely Yttrium, Barium, Copper, and Oxygen, and is regarded as the highest performance and highest stability high temperature superconductor, especially for electric power applications. YBCO has a Perovskite structure. This structure has a complex layering of the atoms in the metal oxide structure. FIG. 1 depicts the structure for YBa₂Cu₃O₇, that include Yttrium atoms 101, Barium atoms 102, Copper atoms 103, and Oxygen atoms 104. For further information on oxide superconductors please see “Oxide Superconductors”, Robert J. Cava, J. Am. Ceram. Soc., volume 83, number 1, pages 5-28, 2000.

A problem with YBCO superconductors specifically, and the oxide superconductors in general, is that they are hard to manufacture because of their oxide properties, and are challenging to produce in superconductor form because of their complex atomic structures. The smallest defect in the structure, e.g. a disordering of atomic structure or a change in chemical composition, can ruin or significantly degrade their superconducting properties. Defects may arise from many sources, e.g. impurities, wrong material concentration, wrong material phase, wrong processing temperature, poor atomic structure, and improper delivery of materials to the substrate, among others.

Thin film YBCO superconductors can be fabricated in many ways including pulsed laser deposition, sputtering, metal organic deposition, physical vapor deposition, and chemical vapor deposition. Two typical ways for the deposition of thin film YBCO superconductors are described here as example. In the first way, the YBCO is formed on a wafer substrate in reaction chamber 200, as shown in FIG. 2 by metal organic chemical vapor deposition (MOCVD). This manner of fabrication is similar to that of semiconductor devices. The wafer substrate is placed on holder 201. The substrate is heated by heater 202. The wafer substrate is also rotated which allows for more uniform deposition on the substrate wafer, as well as more even heating of the substrate. Material, in the form of a gas, is delivered to the substrate by shower head 203, via inlet 204. Shower head 203 provides a laminar flow of the material onto the substrate wafer. The material collects on the heated wafer substrate to grow the superconductor. Excess material is removed from chamber 200 via exhaust port 208, which is coupled to a pump. To prevent undesired deposition of material onto the walls of chamber 200, coolant flows through jackets 205 in the walls. To prevent material build up inside shower head 203, coolant flows through coils 206 in shower head 203. Flanged port 207 allows access to the inside of chamber 200 for insertion and removal of the film/substrate sample. Processing of the film may be monitored through optical port 209.

In the second way depicted in FIG. 3, YBCO is formed by pulsed laser deposition on a substrate, including the possibility of using continuous metal tape substrate 301. Tape substrate 301 is supported by two rollers 302, 303 inside of a reaction chamber 300. Roller 302 includes a heater 304, which heats tape 301 up to a temperature that allows YBCO growth. Material 305 is vaporized in a plume from a YBCO target by irradiation of the target by typically an excimer laser 306. The vapor in the plume then forms the YBCO superconductor film on substrate 301. Rollers 302, 303 allow for continuous motion of the tape past the laser target thus allowing for continuous coating of the YBCO material onto the tape. Note that laser 306 is external to chamber 300 and the beam from laser 306 enters chamber 300 via optical port 307. The resulting tape is then cut, and forms a tape or ribbon that has a layer of YBCO superconductive material.

Neither of the above described methods for forming thin film high temperature superconductors can produce a long length tape or ribbon of YBCO which can be used to replace copper (or other metal) wires in electric power applications. The first way only allows for the production of small pieces of superconductor material on the wafer, e.g. a batch process. The second way can only be used to make tape that is a few feet in length and uses multiple passes to generate a superconductor film of several microns thickness. The second way has a practical limitation of about 5 feet. Larger pieces of tape would require a larger heating chamber. A larger heating roller will also be needed. The tape will cool down after leaving roller 302, and thus will need more time to heat back up to the required temperature. Heating on one side of the chamber, with a cool down on the other side of the chamber may also induce thermal cracks into the YBCO layer and other layers formed on the metal substrate. The smaller pieces of tape produced by the second method may be spliced together to form a long length tape, but while the pieces may be superconducting, splice technology is not yet at the point of yielding high quality high temperature superconductor splices. Consequently, current arrangements for forming superconductors cannot form a long, continuous tape of superconductor material.

### BRIEF SUMMARY OF THE INVENTION

The present invention is directed to a system and method which imparts quality control testing to a reel-to-reel superconductor manufacturing line. The manufacturing line uses a pay-out reel to dispense the tape substrate. The manufacturing line includes various stages to form the superconductor layer onto the tape substrate, including an initialization stage, a deposition stage, and an anneal stage. The manufacturing line includes a take-up reel to spool the superconductor tape.

The quality testing may be performed in a separate stage before the initialization stage, after the initialization stage, after the deposition stage and/or after the anneal stage, or combinations thereof. The quality control testing will ensure the characteristics of the final superconductor tape, as well as the tape under process. The quality control testing may be used to control and/or change production parameters (e.g. temperature, pressure, gas concentrations, precursor amounts, etc). The quality testing may be incorporated into one or more of the initialization stage, the deposition stage, and the anneal stage. For example, the deposition stage may comprise one or more reactors, and quality control testing system(s) may be built into one or more of the reactors. As another example, transition chambers are used between each stage and between each reactor, and quality control testing system(s) may be built into one or more of the transition chambers. Note that quality control testing may be performed separately from the production line.

The quality control may incorporate direct or indirect measurement of superconductor properties including atomic order, temperature, reflectivity, surface morphology, thickness, microstructure, T_{c}, J_{c}, microwave resistivity, etc., or the direct or indirect measurement of the properties of the buffer layers or the coating layers of the tape including atomic order, temperature, reflectivity, surface morphology, thickness, microstructure, etc, as well as measurements of the tape substrate.

One embodiment of the invention may use a microwave measurement system to determine the surface resistance and/or dielectric properties of the tape substrate, a buffer layer, and/or the superconductor layer. This system may include a quarter wave coaxial resonator or a far field resonator. This system may be located in a transition chamber, a reactor, or in a separate testing chamber.

Another embodiment uses an ion scattering system to determine the atomic order and/or composition of the tape substrate, a buffer layer, and/or the superconductor layer. This system may use a time-of-flight detector to determine the composition of the layer under test. This system may also use one or more detectors set at predetermined angles to detect scattered ions to determine the atomic order of the layer under test.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 depicts a known atomic structure for a YBCO superconductor;

FIG. 2 depicts a first prior art arrangement for producing a YBCO superconductor;

FIG. 3 depicts a second prior art arrangement for producing a YBCO superconductor;

FIG. 4 depicts exemplary system 400 according to various embodiments of the invention;

FIG. 5 depicts exemplary quality testing system 501 that is included in a reactor, according to various embodiments of the invention;

FIG. 6 depicts an alternative to the arrangement of the system of FIG. 5, according to various embodiments of the invention;

FIG. 7 depicts exemplary quality testing system 701 that is included in a transitional chamber, according to embodiments of the invention; and

FIG. 8 depicts an alternative to the arrangement of FIG. 7, according to embodiments of the invention.

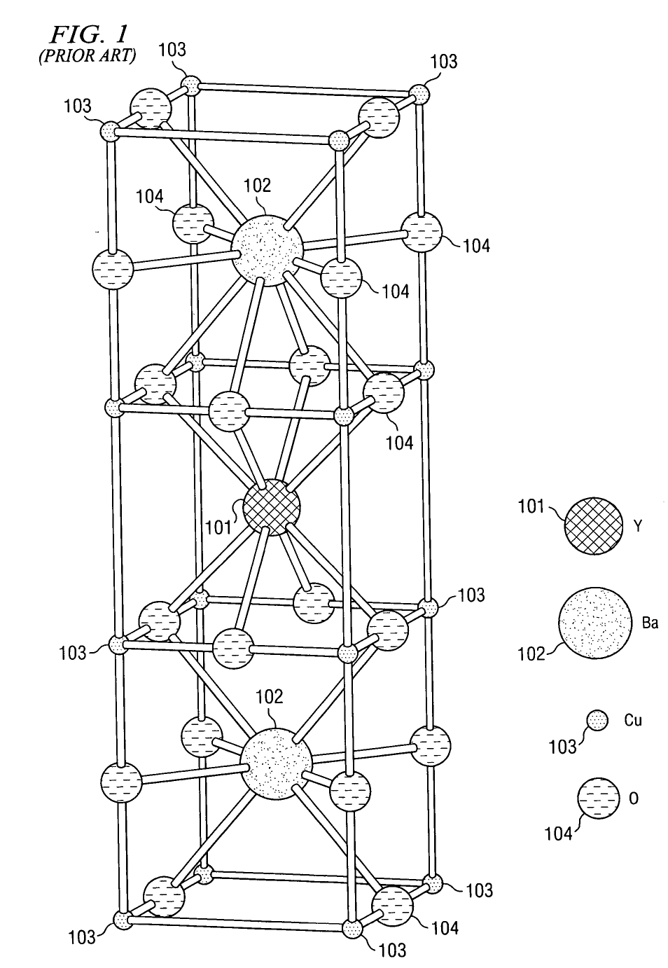

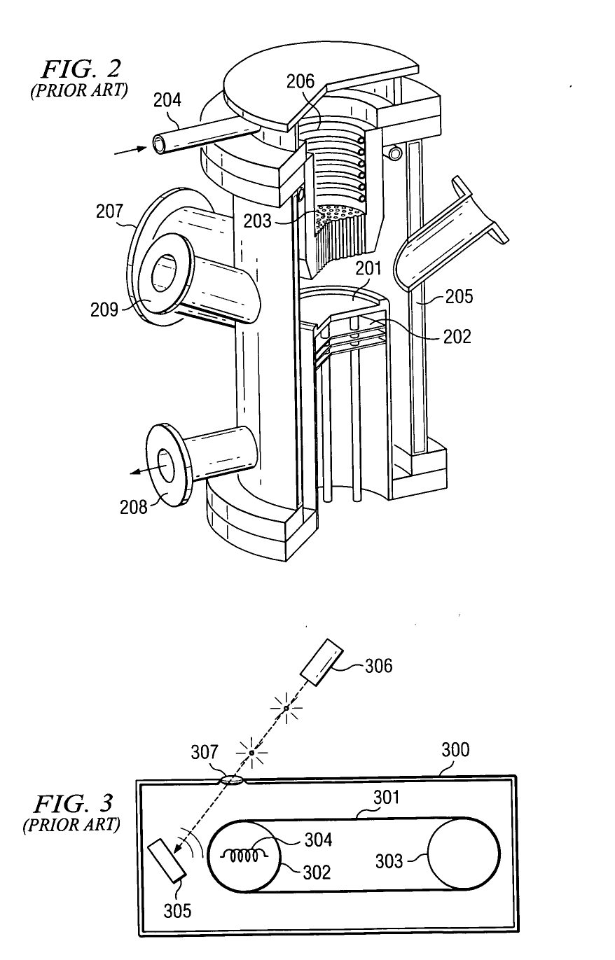

### DETAILED DESCRIPTION OF THE INVENTION

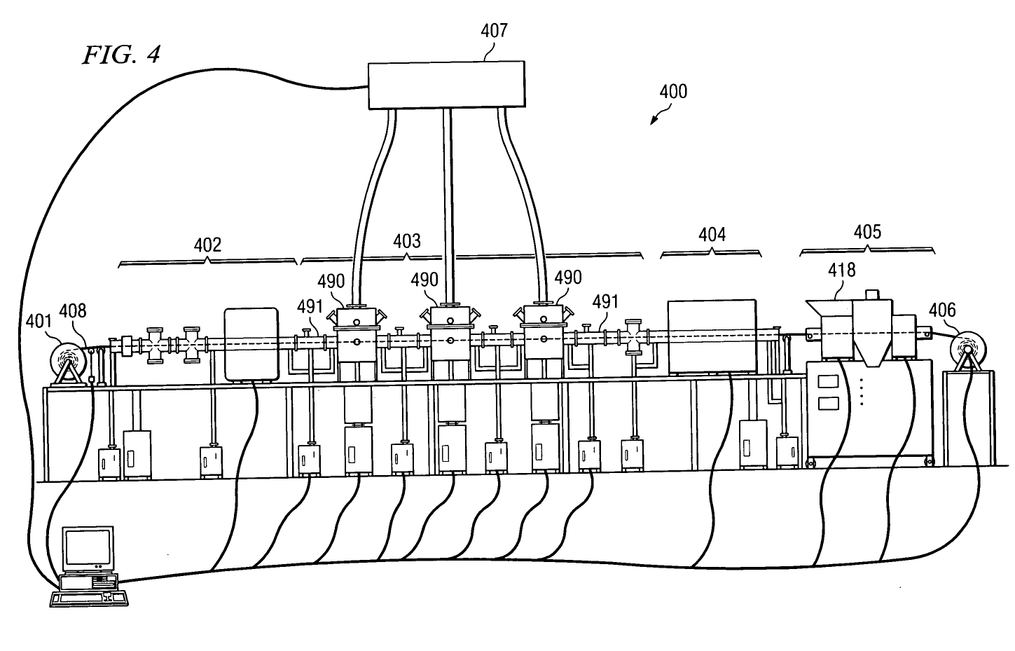

FIG. 4 is a schematic diagram of an embodiment of exemplary system 400 that produces a continuous tape of high temperature super-conducting (HTS) material. System 400 includes several stages that operate together to deposit superconductor material onto a metallic substrate, such that the HTS material is atomically ordered with large, well-oriented grains and principally low angle grain boundaries. The atomic ordering allows for high current densities, e.g. J_{c} greater than or equal to 100,000 amps per cm².

System 400 uses pay-out reel 401 to dispense tape 408, which is a ribbon of substrate at this point in the process, at a constant rate. The system then uses initialization stage 402 to pre-heat and/or pre-treat tape 408 before growing the superconductor layer and any buffer layers) thereon. Pre-heating may be desirable to lessen thermal shock of the substrate. Pre-treating may also be desirable to reduce contaminants from the substrate before growing the superconductor layer. The system then uses deposition stage 403 that has at least one reactor or reaction chamber 490 to deposit one or more materials onto tape 408 that is used to form the superconductor layer. The number of reactors needed may depend upon a number of factors, including the type of superconductor material that is being formed, the type and number of buffer layers that are needed (if any) between the superconductor material and the substrate, and the type of substrate that is used to support the superconductor material. The system uses anneal stage 404 to finalize the superconductor layer and cool down the superconductor tape. The system uses take-up reel 406 to spool the superconductor tape.

System 400 may include one or more transition chambers 491 between initialization stage 402 and the reaction chambers, between the reaction chamber and anneal stage 404, and between reaction chambers if more than one reaction chamber is used. Additional reaction chambers or reactors may be used to provide buffer layers between substrate 408 and the high temperature superconductor (HTS) film, or coating layers on top of or in between layers of the HTS film. The transition chambers isolate each stage or reactor from the other stages and/or reactors, and thereby prevent cross-contamination of materials from one stage or reactor to another stage or reactor.

The system may be used to form superconductor tape from different superconductor materials, including, but not limited to YBa₂Cu₃O₇₋ₓ, YBCO, NdBa₂Cu₃O₇₋ₓ, LaBa₂Cu₃O₇₋ₓ, Bi₂Sr₂Ca₂Cu₃O_{y}, Pb₂₋ₓBiₓSr₂Ca₂Cu₃O_{y}, Bi₂Sr₂CaCu₂O_{z}, Tl₂Ba₂CaCu₂Oₓ, Tl₂Ba₂Ca₂Cu₃O_{y}, TlBa₂Ca₂Cu₃O_{z}, Tl₁₋ₓ BiₓSr_{2-y}Ba_{y}Ca₂Cu₄O_{z}, TlBa₂Ca₁Cu₂O_{z}, HgBa₂CaCu₂O_{y}, HgBa₂Ca₂Cu₃O_{y}, MgB₂, copper oxides, rare earth metal oxides, and other high temperature superconductors. Furthermore, embodiments may operate for many different thin film deposition processes, including but not limited to metalo-organic chemical vapor deposition (MOCVD), pulsed laser deposition, DC/RF sputtering, metal organic deposition, molecular beam epitaxy, and sol gel processing.

System 400 includes quality control testing to ensure the proper characteristics of the final superconductor tape, as well as the tape under process. The quality control testing may be incorporated at any of reactors 490, in any of transition chambers 491, and/or at pre-treat 402 or post-anneal stages 404. The quality control testing may be located in a separate stage, e.g. testing stage 418. The quality control testing may incorporate direct or indirect measurement of YBCO properties including atomic order, temperature, reflectivity, surface morphology, thickness, microstructure, T_{c}, J_{c}, microwave resistivity, etc., or the direct or indirect measurement of the properties of the buffer layers or the coating layers of the tape including atomic order, temperature, reflectivity, surface morphology, thickness, microstructure, etc. Note that J_{c} is the critical current density, i.e, the maximum amount of current that the wire can handle before breakdown. Some superconductor elements may have a J_{c} of 100,000 amps/cm² or greater. Good superconductor elements may have a J_{c} of 500,000 amps/cm² or greater.

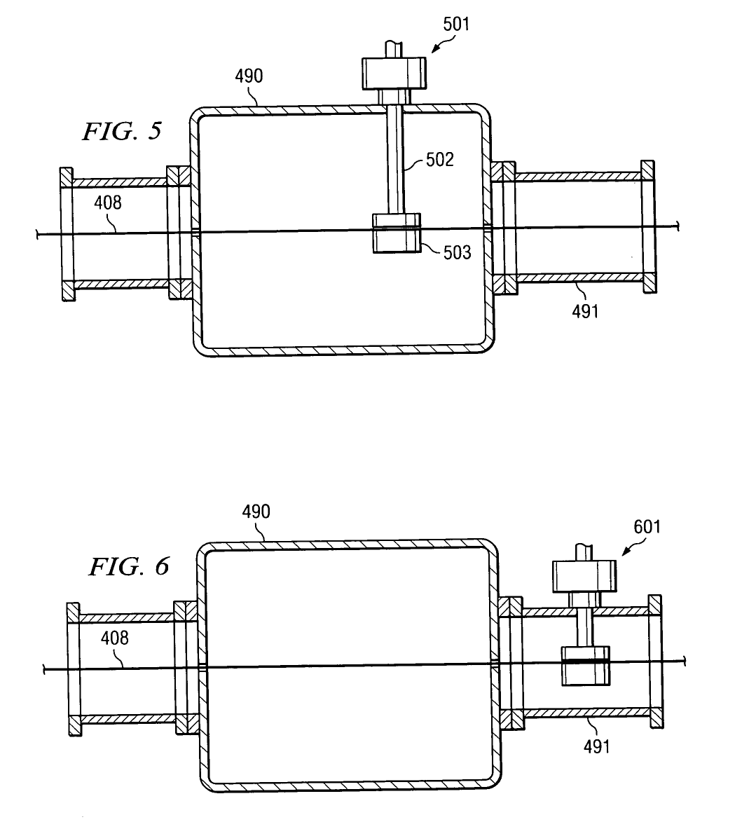

FIG. 5 depicts an embodiment of a quality testing system 501 that may be included in one of reactors 490. System 501 is a microwave measurement system that provides a measure of the surface resistance of the tape, as well as its dielectric properties. To measure the superconductor layer, system 501 may be placed in the reactor that deposits the superconductor layer. It is desirable to perform measurements as close to the deposition area as possible. Thus, if any errors in the deposited layers are detected, then the errors may be corrected more quickly by appropriately adjusting the deposition parameters. The quicker the correction, the less erroneous superconductor tape is produced. Similarly, to measure a buffer layer, system 501 may be placed in the reactor that deposits the buffer layer.

There is a useable correlation between the surface resistance at high temperature (e.g. 600 degrees C.) and the superconducting quality of the tape at superconducting temperatures (e.g. liquid nitrogen temperature). Thus, the lower the resistance at high temperature, the better the superconductor layer.

System 501 includes microwave emitter/receiver 502 and quarter wave coaxial resonator 503 that surrounds tape 408. Such resonators are commercially available from a number of sources (e.g. Integrated Microwave, Mite Q, etc). Microwaves are emitted from emitter 502 and are directed to coaxial resonator 503 that includes tape 408. Tape 408 affects the microwave energy, and a portion of the energy is reflected back to receiver 502. The surface resistance of tape 408, as well as, the dielectric properties then can be determined through known methods

System 501 may provide a high resolution measurement for a small area of tape 408. The measurements may be taken continuously, as tape 408 moves through system 501. Any changes to quality are usually be detected quickly, thus allowing the production process to be changed to correct for any error. Note that a plurality of these systems may be used, each of which may be deployed across the width of tape 408 (orthogonal to the direction of movement), and, thus, each measuring a different strip of the tape.

Note that system 501 may use far-field resonator 501 instead of a quarter wave resonator 503. A far-field resonator may allow for a larger area of tape 408 to be measured (e.g. 5 mm square), but while providing a lower resolution measurement than quarter wave resonator 503. The far field resonator may also be useful in measuring the dielectric constant of tape 408. From the dielectric constant, the thickness and quality of the layer of interest (either buffer or superconductor) may be determined. The dielectric constant may be a good indicator of, for example, the quality of the one or more buffer layers by indicating thickness and purity.

Such far-field resonators are commercially available from a number of sources (e.g. Integrated Microwave, Mite Q, etc). In such a system, microwaves are emitted from emitter 502 and are directed to a coaxial resonator, which may be similar to resonator 503, that includes tape 408. Tape 408 affects the microwave energy, and a portion of the energy is reflected back to the receiver 502. The surface resistance of the tape, as well as the dielectric properties, then can be determined through known methods. It should be noted that the material used to construct a quality testing system, such as system 501, should be constructed such that parts exposed to the inside of system 400 are appropriately stable. For example, parts that are exposed in one of reactors 490 or transition chambers 491 should be high-temperature stable because of the heat in those areas.

FIG. 6 depicts an alternative arrangement for the embodiment of system 501 of FIG. 5. In FIG. 6, quality testing system 601 is located in transition chamber 491. This location, while more distant from the layer formation than the arrangement of FIG. 5 may be more beneficial, as the environment in transition chambers 491 may be less extreme in terms of heat, pressure and gases than the environment of reactors 490. Moreover, reactors 490 have deposition materials which may build up on quality testing system 601 which would not be present in transition chamber 491, thus possibly affecting the measurement results and/or damaging quality testing system 601. Note that as a further alternative arrangement, quality testing system 601 may be located in a separate stage, e.g. testing stage 418. Note that multiple instantiations of the testing systems of FIGS. 5 and 6 may be present in system 400, e.g., one to test tape 408 located after stage 402, another one located in deposition stage 403 to test a buffer layer, another one located in deposition stage 403 to test the superconductor layer, and/or another one located after anneal stage 404 to test the superconductor layer.

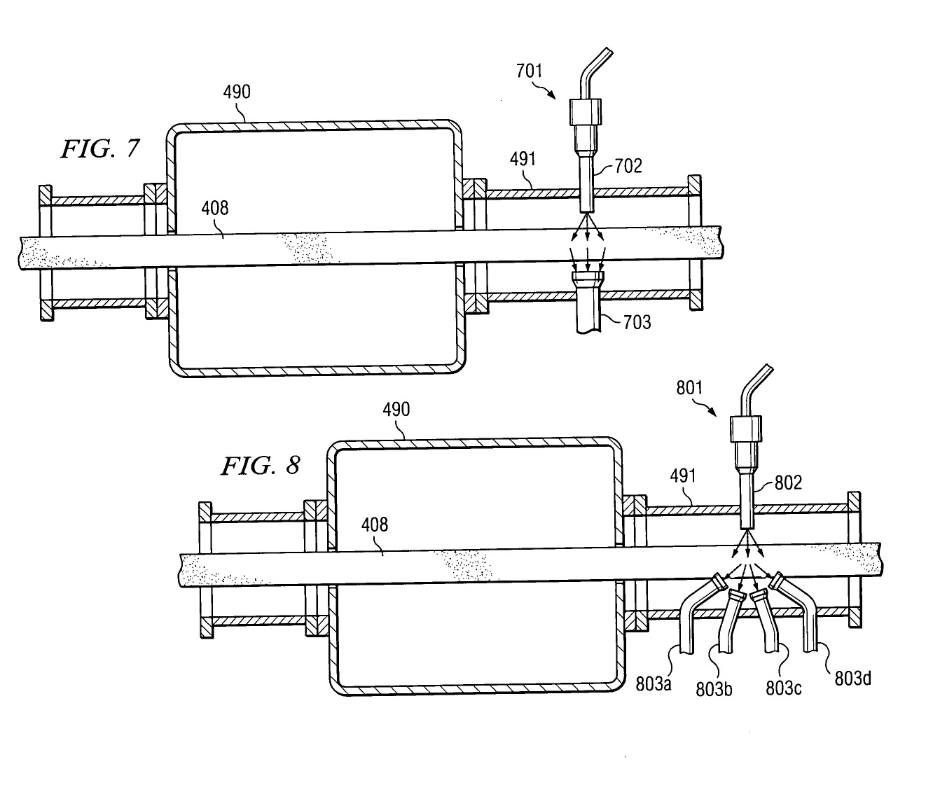

FIG. 7 depicts quality testing system 701 that may be included in one or more of transition chambers 491. Note that FIG. 7 is a top-down view. Quality system 701 uses ion scattering to determine the atomic order and composition of tape 408. Quality system 701 has an ion emitter 702 which directs charged ions toward the surface of tape 408, at a glancing angle with respect to the surface of tape 408, e.g., 15 to 40 degrees. The ions scatter off the surface and also dislodge material from the surface. The ions and/or the material would scatter at different angles, and are received by detector 703. The angles may be measured, from which the atomic order of the surface and well as the composition may be determined. Examples of ions include inert gas ions (e.g. Ar+), and cesium ions.

Detector 703 may be a time-of-flight detector. This type of detector allows for the determination of mass resolution of the dislodged material so that the composition of the surface can be determined. Note that the ion density is low so that very little material is dislodged, which will not affect the properties of the layer being examined. Thus, either the substrate layer, a buffer layer, or the superconductor layer may be examined to ensure that the stoichiometry is correct.

FIG. 8 depicts another embodiment of the arrangement of FIG. 7 that has multiple detectors 803a-803d. Note that FIG. 8 is a top-down view. Each detector is aligned at a predetermined angle with respect to emitter 802 and tape 408. The ions from emitter 802 would impact the surface of tape 408 and scatter at predetermined angles based on the atomic ordering of the material. Each detector may be set to one of the angles, and thus would be used to determine if the layer has the proper atomic ordering. In other words, if ions are not received by one or more of the detectors, then the layer does not have the proper atomic ordering or composition. This ensures that the layer has the right composition and ordering.

Note that with multiple detectors, one (or more) of the detectors may be a time-of-flight detector to determine the composition based on dislodged material of the layer, and the others may be set to receive properly scattered ions to determine atomic ordering of the layer.

This quality system may be preferably located in one of transition chambers 491, since this type of testing usually needs to be conducted in a high vacuum, e.g. 10⁻³ Torr or lower, and with little or no background gas. The measurements may be taken continuously, as the tape moves through system 701. Any changes to quality would be detected quickly, and allow the production process to be changed to correct for any error.

Note that as a further alternative arrangement, the quality testing system may be located in a separate stage, e.g. testing stage 418. Note that multiple instantiations of the testing systems of FIGS. 7 and 8 may be present in the system, e.g. one to test tape 408 located after stage 402, another one located in deposition stage 403 to test a buffer layer, another one located in deposition stage 403 to test the superconductor layer, and/or another one located after anneal stage 404 to test the superconductor layer.

Further note that any combination of testing systems of FIGS. 5, 6, 7, and 8 may be used in one production system.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A system for forming a superconductor wire with a tape substrate comprising:
a deposition apparatus including:
a first reel for dispensing the tape substrate;
at least one deposition chamber that receives the tape substrate from the first reel and forms a layer of superconductor material on the tape substrate; and
a second reel that spools the tape substrate with the layer of superconductor material from the at least one deposition chamber; and
a quality control testing device at least partially inside the deposition apparatus arranged to provide measurement of a characteristic of one of the tape substrate and the layer of superconductor material.

2. The system of claim 1 wherein the quality control testing device is a microwave measurement system.

3. The system of claim 2 wherein the microwave measurement system includes a resonator selected from the following list:
a coaxial resonator; and
a far-field resonator.

4. The system of claim 2 wherein the microwave measurement device is located inside the deposition chamber.

5. The system of claim 2 wherein the deposition apparatus further comprises a transition chamber, and wherein the microwave measuring device is located inside the transition chamber.

6. The system of claim 2 wherein the microwave measuring device is operable to measure a resistivity of the superconductor layer.

7. The system of claim 1 wherein the quality control testing device is an ion-scattering device.

8. The system of claim 7 wherein the deposition apparatus further comprises a transition chamber, and wherein the ion scattering device is located inside the transition chamber.

9. The system of claim 7 wherein the ion-scattering device is a time-of-flight detector.

10. The system of claim 7 wherein the ion scattering device includes a plurality of detectors, each of the detectors positioned at different angles.

11. The system of claim 7 wherein the ion-scattering device is positioned at a glancing angle with respect to the tape substrate.

12. The system of claim 1 wherein the deposition apparatus further comprises a buffer layer deposition chamber and a transition chamber between the deposition chambers, wherein the buffer layer deposition chamber and the transition chamber each include other quality testing devices at least partially therein.

13. A system for forming a superconductor wire with a tape substrate comprising:
a deposition apparatus including:
means for dispensing the tape substrate;
means for receiving the tape substrate from the first reel and for forming a layer of superconductor material on the tape substrate; and
means for spooling the tape substrate with the layer of superconductor material from the at least one deposition chamber; and
means for providing a measurement of a characteristic of one of the tape substrate and the layer of superconductor material, arranged at least partially inside the deposition apparatus.

14. The system of claim 13 wherein the measurement providing means is a microwave measurement system.

15. The system of claim 14 wherein the microwave measurement device is located inside the receiving means.

16. The system of claim 14 wherein the deposition apparatus further comprises a transition chamber, and wherein the measurement providing means is located inside the transition chamber.

17. The system of claim 2 wherein the measurement providing means comprises means for measuring a resistivity of the superconductor layer.

18. The system of claim 13 wherein the measurement providing means is an ion-scattering device.

19. The system of claim 7 wherein the deposition apparatus further comprises a transition chamber, and wherein the measurement providing means is located inside the transition chamber.

20. The system of claim 13 wherein the receiving means further comprises a buffer layer deposition chamber and a transition chamber between the deposition chambers, wherein the buffer layer deposition chamber and the transition chamber each include other measurement providing means arranged at least partially therein.

21. The system of claim 13 wherein the dispensing and spooling means are exposed to normal atmosphere, such that the deposition apparatus is an air-to-air device.

22. A method for forming a superconductor wire with a tape substrate using a deposition apparatus comprising:
dispensing the tape substrate;
receiving the tape substrate from the first reel into a deposition chamber and forming a layer of superconductor material on the tape substrate;
spooling the tape substrate with the layer of superconductor material from the at least one deposition chamber; and
providing a measurement of a characteristic of one of the tape substrate and the layer of superconductor material using a quality testing device arranged at least partially inside the deposition apparatus.

23. The method of claim 22 wherein providing a measurement comprises using a microwave measurement device inside the deposition chamber to determine a surface resistance of the superconductor layer.

24. The method of claim 22 wherein providing a measurement comprises using a microwave measurement device inside the deposition chamber to determine a dielectric property of a buffer layer on the tape substrate.

25. The method of claim 22 wherein providing a measurement comprises using an ion-scattering device to determine an atomic order of the superconductor layer.

26. A system for forming a superconductor wire with a tape substrate comprising:
a deposition apparatus including:
a first reel for dispensing the tape substrate;
a first reaction chamber arranged to receive the tape substrate from the first reel and forms a layer of buffer material on the tape substrate;
a second reaction chamber arranged to receive the tape substrate with the layer of buffer material and to form a layer of superconductor material on the buffer layer;
a transition chamber between the first and second reaction chambers a second reel that spools the tape substrate with the buffer layer and layer of superconductor material from the second reaction chamber; and
a quality control testing device at least partially inside the deposition apparatus arranged to provide measurement of a characteristic of one of the tape substrate, the buffer layer, and the layer of superconductor material.

27. The system of claim 26 wherein the quality control testing device is operable to perform direct or indirect measurement of qualities of the superconductor material from the list consisting of:
atomic order, temperature, reflectivity, surface morphology, thickness, microstructure, T_{c}, J_{c}, and microwave resistivity.

28. The system of claim 26 wherein the quality control testing device is operable to perform direct or indirect measurement of qualities of the buffer material from the list consisting of:
atomic order, temperature, reflectivity, surface morphology, thickness, and microstructure.

29. The system of claim 26 wherein the quality control testing device is a microwave measurement system.

30. The system of claim 29 wherein the microwave measurement system includes a resonator selected from the following list:
a coaxial resonator; and
a far-field resonator.

31. The system of claim 29 wherein the microwave measurement device is located inside one of the first or second deposition chambers.

32. The system of claim 29 wherein the microwave measuring device is located inside the transition chamber.

33. The system of claim 26 wherein the quality control testing device is an ion-scattering device.

34. The system of claim 33 wherein the ion scattering device is a time-of flight-located inside the transition chamber.

35. The system of claim 33 wherein the ion scattering device includes a plurality of detectors, each of the detectors positioned at different angles.
